(19) United States
(12) Patent Application Publication
(10) Pub. No.: US 2008/0266768 A1
(43) Pub. Date: Oct. 30, 2008

(54) Adjustable display

(76) Inventor: Paul L. Drew, The Woodlands, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/796,398

(22) Filed: Apr. 27, 2007

(51) Int. Cl. H05K 5/00

(52) U.S. Cl. 361/681

(57) ABSTRACT

Various embodiments are directed to a display stand having a base and a mounting arm. The mounting arm includes a hinge connected to the base and a hinge connected to the display so the display can move about three different axes of rotation.

### BACKGROUND

In order to meet demands of users, computing devices are becoming more sophisticated and often have a variety of modular and multi-task capabilities. In some computing environments, for example, the display may have to be positioned to various angles and orientations with respect to the base in order to function as both a display for entering data via a keyboard or as a display for entering data with a stylus.

Displays with fixed or limited adjustability do not provide sufficient viewing angles to meet the needs of some users. If a display is rigidly fixed to the base or provided with limited adjustability, then some viewing angles are not available to users. For instance, it may be difficult to position the screen at a preferred viewing distance or at a preferred angle to eliminate distracting reflections. In still other instances, the screen may have to be adjusted to provide an ergonomic position while being used as a touch screen.

### BRIEF DESCRIPTION OF THE DRAWINGS

FIG. 1 is a rear perspective view of a display stand and display according to an exemplary embodiment.

FIG. 2A is side view of a display stand illustrating tilt movement of a display according to an exemplary embodiment.

FIG. 2B is front view of a display stand illustrating pivotal movement of a display according to an exemplary embodiment.

FIG. 2C is top view of a display stand illustrating swivel movement of a display according to an exemplary embodiment.

FIG. 3A is front view of a display stand illustrating moving a display to various angles according to an exemplary embodiment.

FIG. 3B is rear view of a display stand illustrating moving a display to various angles according to an exemplary embodiment.

FIG. 4 is a side view of a display stand and display in a collapsed configuration according to an exemplary embodiment.

### DETAILED DESCRIPTION

Embodiments are directed to a stand for adjusting a display. One embodiment comprises a stand with a dual-hinge and swivel function integrated into a mounting arm of the stand.

In one embodiment, the swivel function is integrated into a top of a dual-hinge arm. The swivel function is located directly behind a display and does not interfere with a height adjustment function.

The stand enables the display to be adjusted to a variety of different positions. By way of example, the display is adjustable around three different axes, such as tilting about an X-axis, pivoting about a Y-axis, and rotating about a Z-axis.

The stand is foldable into a compact configuration that utilizes minimal space for packaging and shipping. In this configuration, the display is in a horizontal position and provides a flat writing surface for use as a tablet personal computer (PC).

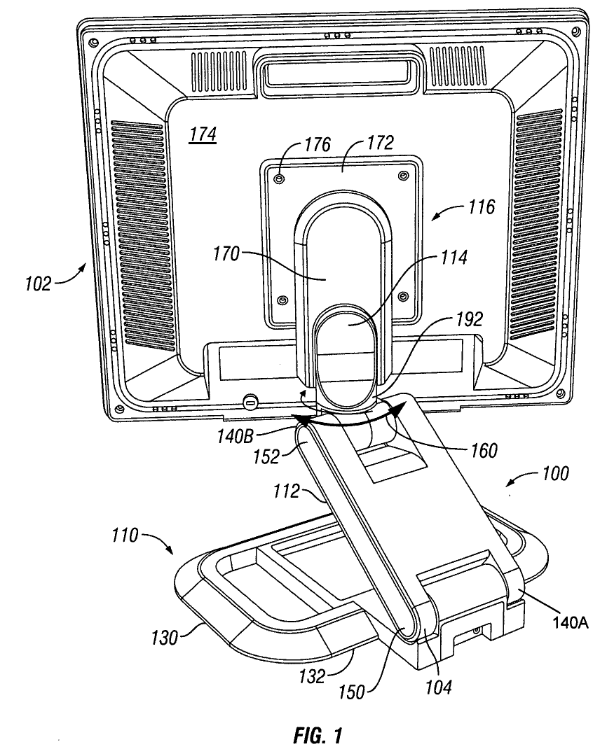

FIG. 1 shows a display stand or stand 100 connected to a display 102. The stand 100 generally comprises a base 110, a mounting arm 112, a swivel 114, and a mounting structure 116.

The base 110 has a rectangular shape with rounded corners and includes a flat side 130 for resting on a surface, such as a desktop. One side 132 of the base connects to an end of the mounting arm 112.

The mounting arm 112 has an elongated straight rectangular shape with rounded ends 140A, 140B. Two separate hinges are provided at the mounting arm. A first hinge or base hinge 150 attaches at the base 110. This base hinge provides a rotational or pivotal point between the mounting arm 112 and the base 110. A second hinge or display hinge 152 attaches at the display 102. This display hinge provides a rotational or pivotal point between the mounting arm 112 and display 102.

In one embodiment, the mounting arm 112 is formed of a strong rigid material (example, metal and/or polymer) and has an elongated straight shape. The mounting arm, however, can have various shapes, such as curved or nonlinear. Further, the mounting arm can be formed of a unitary member or formed of different sections connected together.

The swivel 114 connects to one end of the mounting arm 112 at the display hinge 152 and provides rotational movement of the display 102 (see arrows 160). The display 102 is able to rotate or swivel about the mounting arm 112.

In one embodiment, the display 102 removably attaches to the display stand 100. By way of example, the mounting structure 116 comprises a swivel connector 170 that attaches to one side of the swivel 114. The swivel connector in turn attaches to a plate 172 that connects to a back surface 174 of display 102 using, for example, fasteners 176.

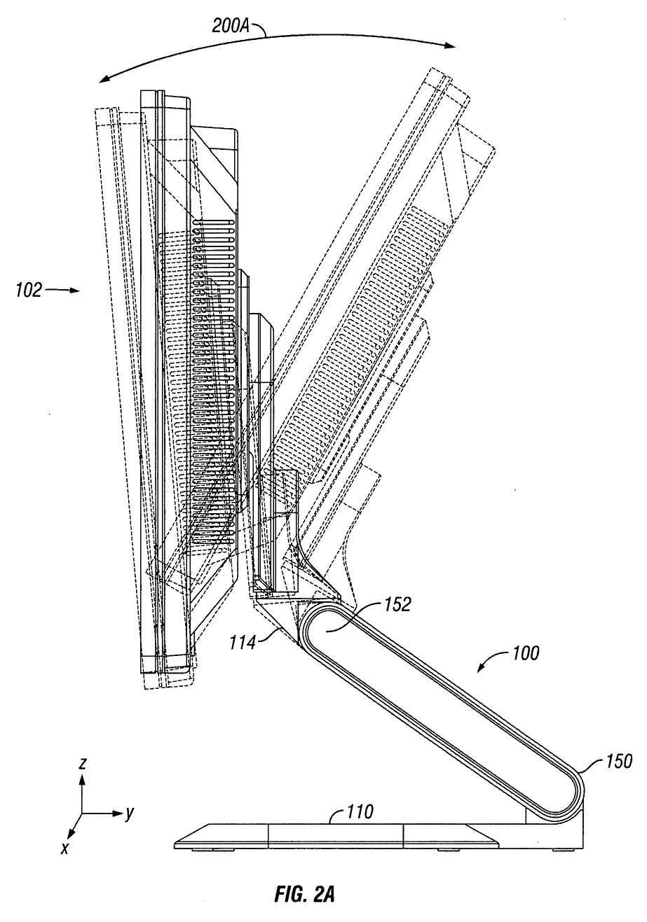

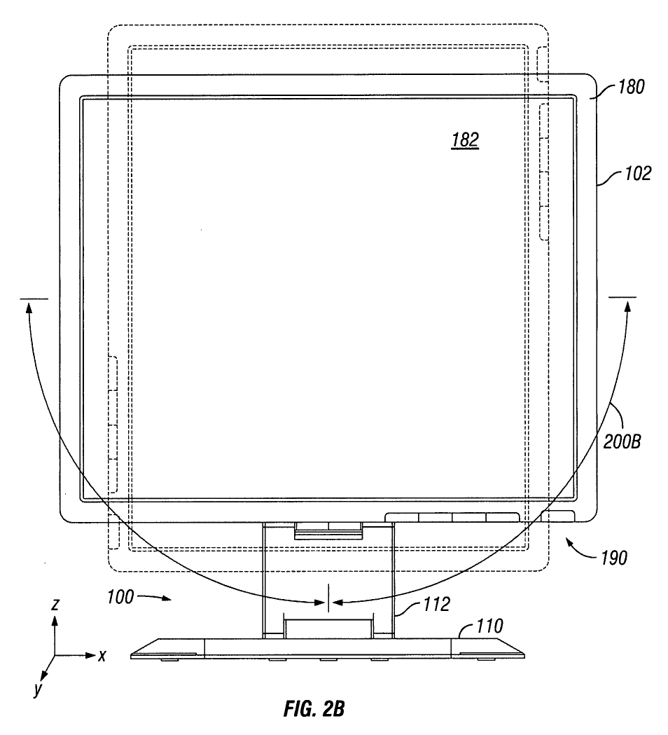

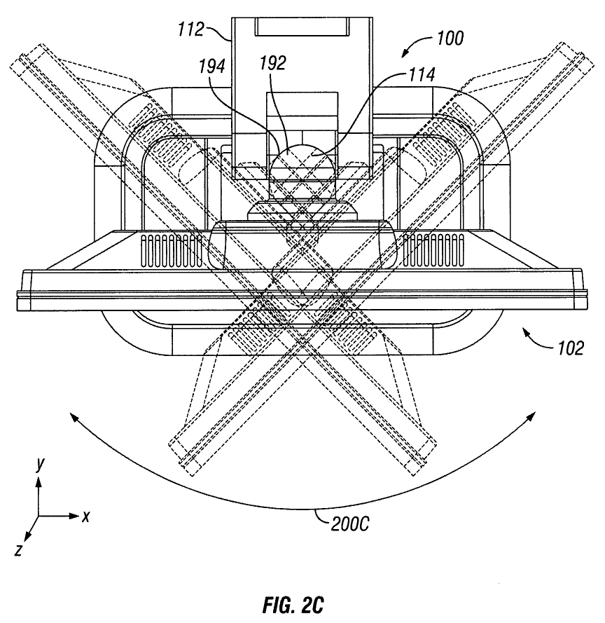

The display 102 generally comprises a back surface 174 and a front surface 180 (FIG. 2B) with a view screen 182. In one embodiment, the screen 182 is a touch-sensitive screen that both displays data and inputs data when touched or activated. By way of example, screen 182 is a backlit color liquid crystal display (LCD) wherein data is entered through the screen using, for example, the stylus or a user's finger. Images that appear on the screen provide a graphical user interface (GUI) and are controlled with software (example, handwriting recognition software) such that displayed images are contacted or activated to input, edit, alter, or otherwise access information. When a user touches or activates a designated area on the screen, for example, the touch-sensitive screen transmits a signal to a processor (example, central processing unit, CPU, located in the display).

The display 102, in some embodiments, functions as a computer, such as a stand-alone personal computer (PC) or a tablet PC. By way of example only, the display 102 includes one or more of a CPU, hard drive, memory, infrared ports, disk drives, PC card slots, batteries, universal serial bus (USB) ports, power connectors, keyboard or monitor connectors, multibays, network connectors, CompactFlash card slots, power connectors, other input/output (I/O) ports, and numerous buttons and switches (such as Enter, Esc, Tab, Menu, Power, etc.), just to name a few examples. Many of these features are generally shown at 190 (FIG. 2B).

The mounting arm 112 couples the display 102 to the base 110 with a dual hinge or two pivotal connections disposed at opposite ends of the mounting arm. Various swivel and hinge-type connections can be used. By way of example, these connections use a cylinder/sleeve connection, ball/socket connection, or other connection that enables two structures to move relative to each other. For instance, the swivel 114 comprises a rounded back portion 192 that rotates in a cylindrical or curved recess 194 in display hinge 152 (FIGS. 1 and 2C).

In one embodiment, the hinges 150, 152 and swivel 114 use friction as a means to maintain the mounting arm in locked or sturdy positions. For example, when sufficient rotational force or torque is applied to display 102, the frictional forces in hinges 150, 152 and swivel 114 are overcome so the display 102 rotates or moves. Once the user has released the display, the frictional forces in the hinges 150, 152 and swivel 114 maintain the display 102 in the desired position.

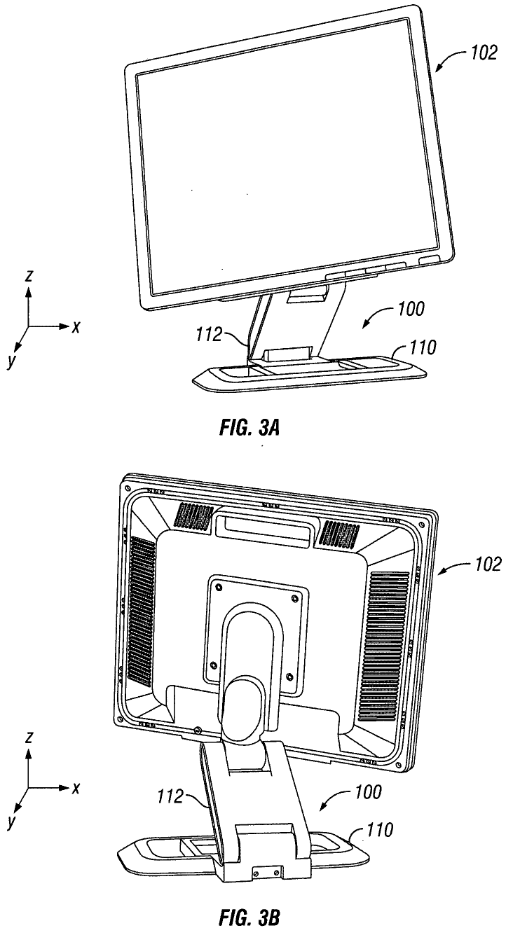

The mounting arm 112 couples the display 102 to the base 110 such that the display is movable to a plurality of different positions. FIGS. 2A-2C and 3A-3B illustrate some of these positions. In order to illustrate the various movements of the display 102, a three-axis coordinate system is shown having an X-axis, a Y-axis, and a Z-axis.

FIG. 2A shows a side view of the display stand 100 and display 102. The display 102 is rotatable or movable along the X-axis about display hinge 152 (various positions of the display shown in phantom). The display is thus able to tilt or rotate through an angle of displacement, shown as arrow 200A. In one embodiment, the display tilts about the X-axis at least about 90 degrees or more from a first position with the display being vertical with respect to the surface (Y-axis) to a second position with the display being horizontal (i.e., flat) with respect to the surface (Y-axis). Tilting of the display 102 occurs while the base 110 and mounting arm 112 remain stationary.

The base hinge 150 enables the vertical position or height of the display 102 to change with respect to the base 110 or surface on which the base is positioned. As base hinge 150 rotates or moves about the X-axis, the display 102 is raised or lowered. Raising or lowering of the display can occur without rotating or moving the display about the swivel 114 and/or display hinge 152.

FIG. 2B shows a front view of the display stand 100 and display 102. The display 102 is rotatable or movable along the Y-axis about swivel 114 (FIG. 1). The display is thus able to pivot or rotate through an angle of displacement, shown as arrow 200B. In one embodiment, the display pivots about 90 degrees or more in either a clockwise or counterclockwise direction about the Y-axis to move between a landscape position and a portrait position (shown in phantom). Pivoting of the display 102 occurs while the base 110 and mounting arm 112 remain stationary.

FIG. 2C shows a top view of the display stand 100 and display 102. The display 102 is rotatable or movable along the Z-axis about swivel 114 (various positions of the display shown in phantom). The display is thus able to swivel or rotate through an angle of displacement, shown as arrow 200C. In one embodiment, the display rotates about 45 degrees or more in either a clockwise or counterclockwise direction about the Z-axis. Swiveling of the display 102 occurs while the base 110 and mounting arm 112 remain stationary.

In one embodiment, the display 102 is independently movable about one or more of the three axes. For instance, the display is movable about a single axis (i.e., about only one of the X-axis, the Y-axis, or the Z-axis). Alternatively, the display is movable about two of the axes or all three of the axes.

By way of illustration, FIGS. 3A and 3B illustrate the display 102 moved about plural different axes. Specifically, the display is tilted about the X-axis, rotated about the Y-axis, and swiveled about the Z-axis.

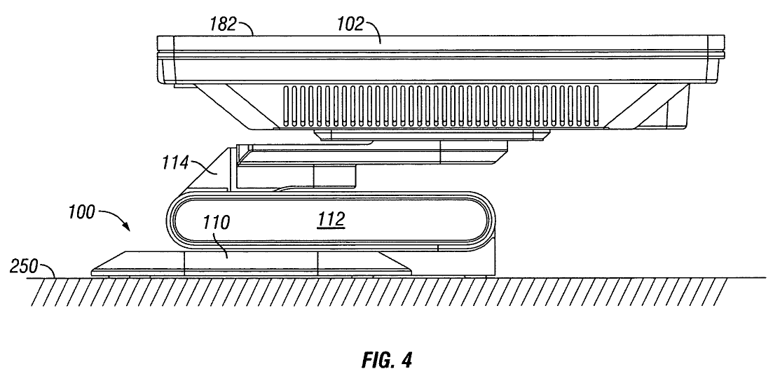

FIG. 4 is a side view of the display stand 100 and display 102 in a collapsed configuration. In this configuration, the screen 182 is in a horizontal position and parallel with the base 110, the mounting arm 112, and a surface 250, such as a desktop. In a collapsed position, the display stand and display are compact for shipping or transport. Further, the display has a flat or horizontal position so it can be used as a writing surface as a tablet PC.

While the invention has been disclosed with respect to a limited number of embodiments, those skilled in the art will appreciate, upon reading this disclosure, numerous modifications and variations. It is intended that the appended claims cover such modifications and variations and fall within the true spirit and scope of exemplary embodiments.

1. An apparatus, comprising:
a base;
an electronic display;
a mounting arm including a first end pivotally connected to the base and a second end pivotally connected to the display such that the display rotates at the second end about an X-axis, a Y-axis, and a Z-axis.

2. The apparatus of claim 1 further comprising, a swivel connected at the second end between the mounting arm and the display.

3. The apparatus of claim 1, wherein the display tilts about the X-axis, pivots about the Y-axis, and swivels about the Z-axis.

4. The apparatus of claim 1, wherein the mounting arm collapses so the display is horizontally positioned on top of and parallel with the base and the mounting arm.

5. The apparatus of claim 1, wherein the mounting arm has an elongated rectangular configuration with rounded ends.

6. The apparatus of claim 1, wherein the mounting arm moves about one axis of rotation at the first end and about three axes of rotation at the second end.

7. The apparatus of claim 1, wherein the display is movable between portrait and landscape positions and between vertical and horizontal positions with respect to a support surface.

8. A display stand, comprising:
a base;
a mounting arm including a first end with a first hinge connected to the base and a second end with a second hinge connected to an electronic display that moves about three different axes at the second hinge.

9. The display stand of claim 8, wherein the mounting arm has an elongated rectangular shape.

10. The display stand of claim 8 further comprising, a swivel connected at the second end of the mounting arm to enable the display to rotate about a horizontal Z-axis.

11. The display stand of claim 8, wherein the three different axes include an X-axis, a Y-axis, and a Z-axis.

12. The display stand of claim 8, wherein the display stand collapses so the mounting arm is positioned on top of and parallel with the base.

13. A method, comprising:
changing a vertical position of an electronic display at a first hinged location of a mounting arm;
tilting the display about an X-axis at a second hinged location of the mounting arm;
pivoting the display about a Y-axis at the second hinged location;
swiveling the display about a Z-axis at the second hinged location.

14. The method of claim 13 further comprising, pivoting the display between a landscape position and a portrait position while the first hinged location remains stationary.

15. The method of claim 13 further comprising, adjusting the display to a horizontal position so the display is parallel with the mounting arm.

16. The method of claim 13 further comprising, swiveling the display at least ninety degrees about the Z-axis.

17. The method of claim 13 further comprising, collapsing the display along the Z-axis so the mounting arm is parallel with and between a base and the display.

18. The method of claim 13, wherein tilting, pivoting, and swiveling the display occur without movement at the first hinged location.

19. The method of claim 13 further comprising, supporting the display with a base attached to the first hinged location.

20. The method of clam 13, wherein the first hinged location attaches to a base that is positioned on a support surface and a swivel attaches to the display at the second hinged location to enable the display to swivel about the Z-axis.
